(19) United States
(12) Patent Application Publication
(10) Pub. No.: US 2010/0310351 A1
(43) Pub. Date: Dec. 9, 2010

(54) METHOD FOR HANDLING AND TRANSFERRING A WAFER CASE, AND HOLDING PART USED THEREFOR

(75) Inventor: Shuji AKIYAMA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/856,244

(22) Filed: Aug. 13, 2010

Related U.S. Application Data
(63) Continuation-in-part of application No. 11/694,325, filed on Mar. 30, 2007.

(30) Foreign Application Priority Data
Mar. 30, 2006 (JP) 2006-095821

(51) Int. Cl. H01L 21/673

(52) U.S. Cl. 414/800; 257/E21.001

(57) ABSTRACT

In a method for handling a wafer case having attachable and detachable grips, the method comprising the step of handling the wafer case e in an automatic transfer line while the attachable and detachable grips are detached from the wafer case and holding parts allowing an automatic transfer unit to hold the wafer case are attached to portions of the wafer case from which the attachable and detachable grips have been detached. The holding parts allow an automatic transfer unit to hold the wafer case.

### CROSS-REFERENCE TO RELATED APPLICATIONS

This is a Continuation-In-Part application of pending U.S. application Ser. No. 11/694,325, filed on Mar. 30, 2007, which claims priority to Japanese Patent Application No. 2006-095821, filed on Mar. 30, 2006.

### FIELD OF THE INVENTION

The present invention relates to a method for handling and transferring a wafer case, and a holding part for use in the wafer case for transferring the wafer case; and, more particularly, to a method for handling a wafer case of a kind to transfer the wafer case between semiconductor manufacturing factories and within a semiconductor manufacturing factory, a method for transferring the wafer case, and a holding part for transferring the wafer case.

### BACKGROUND OF THE INVENTION

As described in Japanese Patent Laid-open Application No. 2002-280445, wafer cases used for transferring a semiconductor wafer include an FOSB (Front Opening Shipping Box) and an FOUP (Front Opening Unified Pod). The FOSB is used when a wafer manufacturer forwards and transfers a wafer to a device manufacturer, and the FOUP is used when a device manufacturer transfers a semiconductor wafer in a semiconductor manufacturing factory. These wafer cases are formed by airtightly sealed containers, and thus, semiconductor wafers are not exposed to air and can be prevented from being contaminated due to particles.

Therefore, conventionally, when the wafer case is handled in a semiconductor manufacturing factory, the semiconductor wafer manufactured by the wafer manufacturer is airtightly sealed in the FOSB and transferred to the device manufacturer. By the device manufacturer, the semiconductor wafer is moved from the FOSB to the FOUP and kept in a stocker, with the semiconductor wafer being located in the FOUP. Further, when various treatments are performed on the semiconductor wafer, the semiconductor wafer is transferred to treatment units of the treatment processes via the FOUP between the treatment processes and in a treatment process by using an unmanned transfer vehicle such as an AGV (Automatic Guided Vehicle), an RGV (Rail Guided Vehicle) or the like. If the treatments of the semiconductor wafer are completed in the treatment processes, the semiconductor wafer is moved from the FOUP to the FOSB before it is forwarded again.

However, in a conventional method of handling a wafer case, an FOSB and an FOUP are used, as the wafer case, for a transfer between factories and for a transfer within a factory, respectively. Therefore, wafer cases of both kinds of the FOSB and the FOUP are necessary, and also, it is required to perform a work of moving the semiconductor wafer between the wafer cases, thereby complicating the method for handling the wafer cases. Further, since the wafer cases of two kinds are necessary, the handling cost of the wafer cases is high.

### SUMMARY OF THE INVENTION

It is, therefore, an object of the present invention to provide a method for handling a wafer case, a method for transferring a wafer case, and a holding part for transferring a wafer case, which can reduce the handling cost by simplifying the handling of a wafer case in a semiconductor manufacturing process.

As a result of examining various ways to use a wafer case of one kind consistently without separately using wafer cases such as an FOSB and an FOUP, the present inventor has found that the cheap FOSB can be consistently used in a transfer between factories, between treatment processes, and in a process without using the expensive FOUP by providing a specific measure in the structure of the FOSB.

In accordance with a first aspect of the present invention, there is provided a method for handling a wafer case having attachable and detachable grips, the method comprising the step of: handling the wafer case e in an automatic transfer line while the attachable and detachable grips are detached from the wafer case and holding parts allowing an automatic transfer unit to hold the wafer case are attached to portions of the wafer case from which the attachable and detachable grips have been detached.

It is preferable that the method further comprises handling the wafer case while the holding parts are detached from the wafer case and the attachable and detachable grips are attached to the wafer case when the wafer case is not handled in the automatic transfer line.

It is preferable that the portions from which the attachable and detachable grips have been detached include two side surfaces of the wafer case, respectively, and the method includes attaching said holding parts to said two side surfaces for handling in the automatic transfer line.

In accordance with a second aspect of the present invention, there is provided a method for transferring a wafer case having attachable and detachable grips, the method comprising the steps of: detaching the attachable and detachable grips from the wafer case, and attaching holding parts allowing an automatic transfer unit to hold the wafer case to portions of the wafer case from which the attachable and detachable grips have been detached, wherein the automatic transfer unit transfers the wafer case while holding the wafer case by using the holding parts.

It is preferable that the method further comprises detachably attaching the attachable and detachable grips to two side surfaces of the wafer case, respectively, when the wafer is not handled in the automatic transfer line.

In accordance with a third aspect of the present invention, there is provided a method for handling the wafer case, further including providing as the holding parts, holding parts which comprise: a manipulation portion for use by the automatic transfer unit; a support for supporting the manipulation portion by a surface thereof; and a connecting portion, formed on another surface of the support, for being connected with a connected portion formed on a side surface of the wafer case.

It is preferable that the method further including providing the connected portion which includes at least one pair of grooves formed on the side surface of the wafer case, and providing the connecting portion which includes at least one pair of engaging portions engaging with said at least one pair of grooves, respectively.

It is preferable that the method further includes providing said at least one pair of grooves as grooves which are formed by protrusions protruding from the side surface of the wafer case in opposite directions with each other, and wherein the pair of engaging portions are formed by engaging protrusions protruding in directions opposite to the protruding directions of the protrusions of said at least one pair of grooves.

It is preferable that the method further includes providing the support is provided with clamping members for fixing the holding part to the wafer case by bringing the connected portion into close contact with the connecting portion.

In accordance with the embodiments of the present invention, there are provided a method for handling a wafer case, a method for transferring a wafer case, and a holding part for transferring a wafer case, which can reduce the handling cost by simplifying the handling of a wafer case in a semiconductor manufacturing process.

### BRIEF DESCRIPTION OF THE DRAWINGS

The above and other objects and features of the present invention will become apparent from the following description of embodiments given in conjunction with the accompanying drawings, in which:

FIGS. 1A and 1B are perspective views showing a holding part used in a method for handling a wafer case in accordance with an embodiment of the present invention, wherein FIG. 1A shows a state before the holding part is mounted to a wafer case and FIG. 1B shows a state just before the holding part is fixed to the wafer case by a clamping member after being mounted thereto;

FIG. 1C illustrates a wafer case with attachable/detachable grips;

FIG. 2 is an enlarged perspective view showing a clamping member of the holding part shown in FIGS. 1A and 1B;

FIGS. 3A to 3C show the clamping member shown in FIG. 2, wherein FIGS. 3A to 3C are plan views showing a front, a rear and a bottom surface of the clamping member, respectively;

FIG. 4 is a perspective view showing a holding part used in a method for handling a wafer case in accordance with another embodiment of the present invention;

FIG. 5 is a cross sectional view showing another example of a groove formed on a side surface of a wafer case used in a method for handling a wafer case in accordance with the present invention;

FIG. 6 is a conceptional plan view showing a method for handling a wafer case in accordance with an embodiment of the present invention; and

FIG. 7 is an enlarged plan view showing a part of a treatment process shown in FIG. 6.

### DETAILED DESCRIPTION OF THE EMBODIMENTS

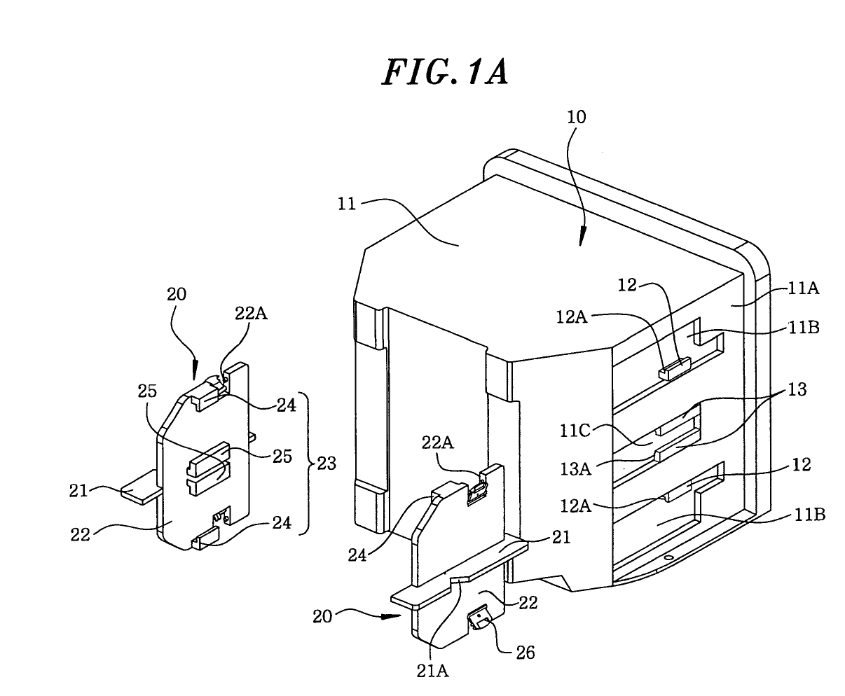

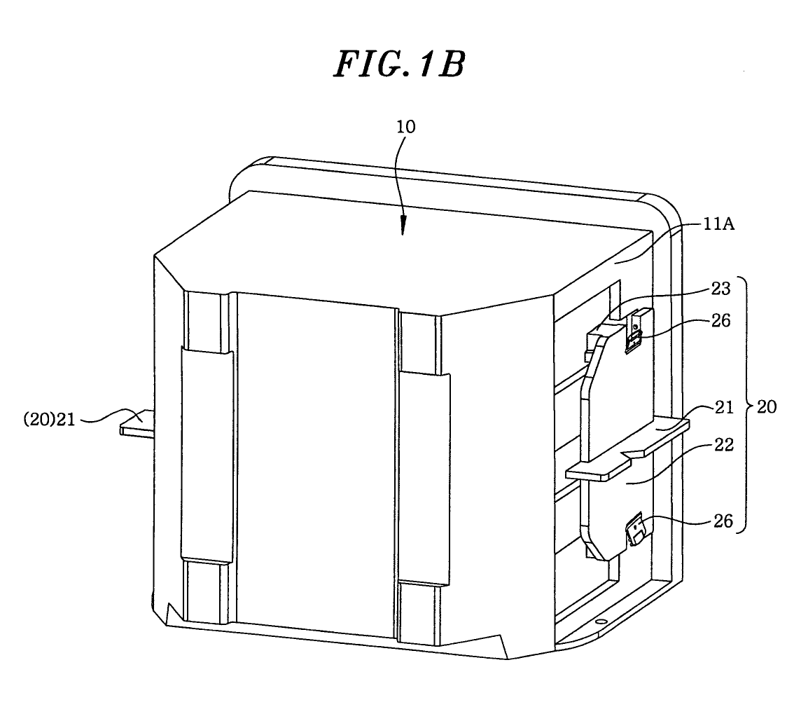

Hereinafter, the present invention will be described according to embodiments shown in FIGS. 1 to 7. Like reference numerals will be given to like parts having substantially the same functions, and redundant description thereof will be omitted in the specification and the accompanying drawings. First, a wafer case used in the embodiments of the present invention will be described with reference to FIGS. 1 to 5. By partially improving a structure of an FOSB conventionally used in a transfer between factories such that a holding part can be attached to the wafer case, the wafer case is adapted to cope with an automatic transfer within a factory. In a factory, e.g., an unmanned transfer vehicle is used as an automatic transfer unit. The unmanned transfer vehicle is equipped with a transfer arm for transporting a wafer case, and thus automatically transports the wafer case between a loading table thereof and a stocker or between treatment units by using the transfer arm.

As shown in FIGS. 1A, 1B, and 1C the wafer case used in the embodiments is formed as, e.g., an FOSB which is used for transferring a plurality of semiconductor wafers between factories and includes a case body 11 accommodating therein the plurality of semiconductor wafers, an opening/closing cover (not shown) attached to a loading/unloading port of the case body 11 for loading and/or unloading the semiconductor wafers, and detachable grips (30, FIG. 1C). A holding part 20 is provided in the wafer case 10 to cope with an automatic transfer by an unmanned transfer vehicle. As shown in FIGS. 1A and 1B, each of the holding parts 20 has a structure capable of being freely mounted and separated to and from one of the two side surfaces 11A of the wafer case 10 while the grips 30 are not attached thereto. The wafer case 10 to which the holding part 20 is mounted can be used as a replacement of an FOUP in a factory. As shown in FIG. 1C, each of the detachable grips 30 has a structure capable of being freely mounted and separated to and from one of the two side surfaces 11A of the wafer case 10 while the holding parts 20 are not attached thereto. The detachable grips 30 have handles 31 so that the wafer case to which the detachable grips 30 are attached can be handled for a transfer between semiconductor wafer factories.

Therefore, in the embodiments, only by providing the holding part 20, the wafer case 10 can be handled for a transfer between semiconductor wafer factories, between treatment processes of semiconductor wafers and in a treatment process, so that wafer cases of both kinds of an FOSB and an FOUP are not necessary as differently from the prior art and a transfer of a semiconductor wafer between an FOSB and an FOUP can be omitted. Accordingly, the handling of the wafer case 10 can be simplified and further the handling cost cab be reduced.

Hereinafter, the wafer case 10 and the holding part 20 will be described in detail. As shown in FIG. 1A, a pair of first protrusions 12 and a pair of second protrusions 13 for mounting and separating the holding part 20 (or the detachable grips 30) are formed on each of the two side surfaces 11A of the wafer case 10 in the vertical direction. To be specific, as shown in FIG. 1A, a first depressed portion 11B (hereinafter, referred to as “upper first depressed portion”), a second depressed portion 11C and another first depressed portion 11B (hereinafter, referred to as “lower first depressed portion”) having substantially rectangular forms are formed at three locations from the upper to the lower portion of each side surface 11A of the wafer case 10. The upper and the lower first depressed portion 11B are disposed to locate the second depressed portion 11C therebetween. One of the first protrusions 12 is formed in the upper and first depressed portion 11B (hereinafter, referred to as “upper first protrusion”) and another one is formed in the lower first depressed portion 11B (hereinafter, referred to as “lower first protrusion”). The side surfaces of the first protrusions 12 are substantially L shaped, and the upper first protrusion 12 is formed along an edge facing the lower first depressed portion 11B and the lower first protrusion 12 is formed along an edge facing the upper first depressed portion 11B. The upper first protrusion 12 forms a groove 12A facing upward in the upper first depressed portion 11B and the lower first protrusion 12 forms a groove 12A facing downward in the lower first depressed portion 11B. Further, in the second depressed portion 11C, a pair of second protrusions 13 having the same shapes as those of the first protrusions 12 is formed along vertically opposite edges (hereinafter, the second protrusions 13 formed along the upper and lower edge of the second depressed portion 11C will be referred to as “upper second protrusion” and “lower second protrusion”, respectively). The upper second protrusion 13 forms a groove 13A facing downward and the lower second protrusion 13 forms a groove 13A.

As shown in FIGS. 1A and 1B, the holding part 20, e.g., includes a manipulation portion 21 for use by an unmanned transfer vehicle (not shown); a plate shaped support 22 supporting the manipulation portion 21 by a surface (front surface) thereof; and a connecting portion 23, formed on the rear surface of the support 22, for connecting the holding part 20 with a connected portion (the first and the second protrusions) formed on the side surface of the wafer case 10. The holding portion 20 is attached to each side surface 11A of the wafer case 10 and then used.

The manipulation portion 21 formed on the front surface of the holding part 20 has a flange-like shape protruding horizontally from the front surface of the plate shaped support 22, as shown in FIGS. 1A and 1B. When the holding part 20 is attached to each side surface 11A of the wafer case 10 as shown in FIG. 1B, the manipulation portions 21 protrude from both side surfaces 11A of the wafer case 10, and thus the wafer case 10 can be supported by a transfer arm of the unmanned transfer vehicle via the manipulation portions 21. A triangular cutoff portion 21A is formed in each manipulation portion 21 to thereby determine the position where the holding part 20 is supported by the transfer arm of the unmanned transfer vehicle (not shown) via the cutoff portion 21A.

As shown in FIG. 1A, the connecting portion 23 formed on the rear surface of the holding part 20 includes a pair of first engaging protrusions 24 and a pair of second engaging protrusions 25, which corresponds to the first and the second protrusions 12 and 13 of the wafer case 10, respectively, and have substantially L shaped side surfaces. One of the first engaging protrusions 24 is formed at the upper end portion of the support 22 (hereinafter, referred to as “upper first engaging protrusion”) and another one thereof is formed at the lower end portion of the support 22 (hereinafter, referred to as “lower first engaging protrusion”). The second engaging protrusions 25 are formed between the upper and the lower first engaging protrusion 24. The upper first engaging protrusion 24 is engaged with the groove 12A of the upper first protrusion 12 of the wafer case 10, thereby being connected with the upper first protrusion 12. The lower first engaging protrusion 24 is engaged with the groove 12A of the lower first protrusion 12 of the wafer case 10, thereby being connected with the lower first protrusion 12. Further, the upper second engaging protrusion 25 is engaged with the groove 13A of the upper second protrusion 13 of the wafer case 10, thereby being connected with the upper second protrusion 13. The lower second engaging protrusion 25 is engaged with the groove 13A of the lower second protrusion 13 of the wafer case 10, thereby being connected with the lower second protrusion 13.

At the upper and the lower end portions of the support 22, upper and lower clamping member 26 are attached to cutoff portions 22A adjacent to the upper and the lower first engaging protrusion 24, respectively. The upper and the lower clamping members 26 endows a force spacing the support 22 apart from the side surface 11A of the wafer case 10 at the upper and the lower portion of the support 22, and thus prevent rattling between the first engaging protrusions and the first protrusions 12 and between the second engaging protrusions 25 and the second protrusions 13 of the wafer case 10, thereby firmly fixing the holding part 20 to the side surface 11A of the wafer case 10. Since the upper and the lower clamping members 26 have an identical structure as shown in FIGS. 1A, 1B, 2 to 3C, the upper clamping member 26 will be described as an example.

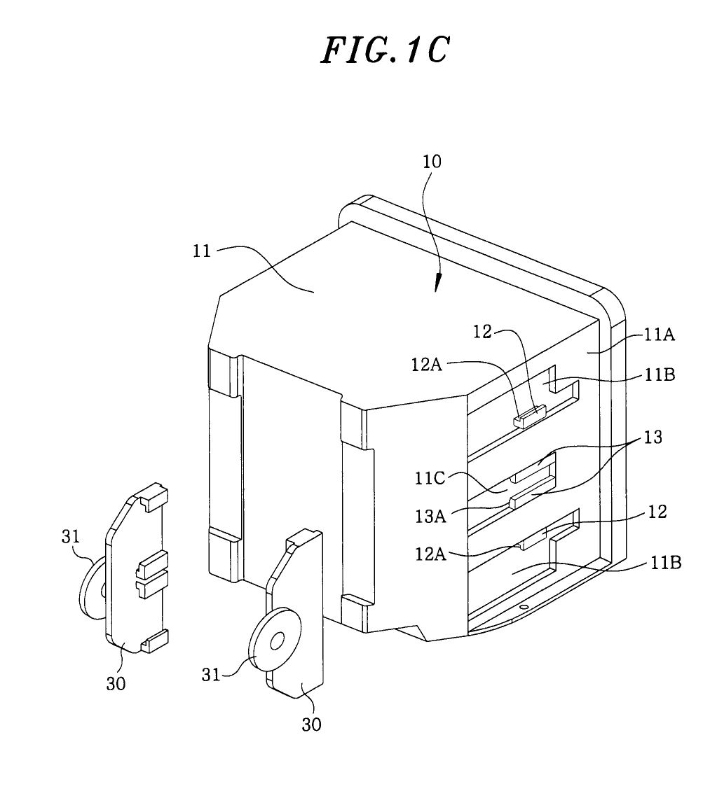

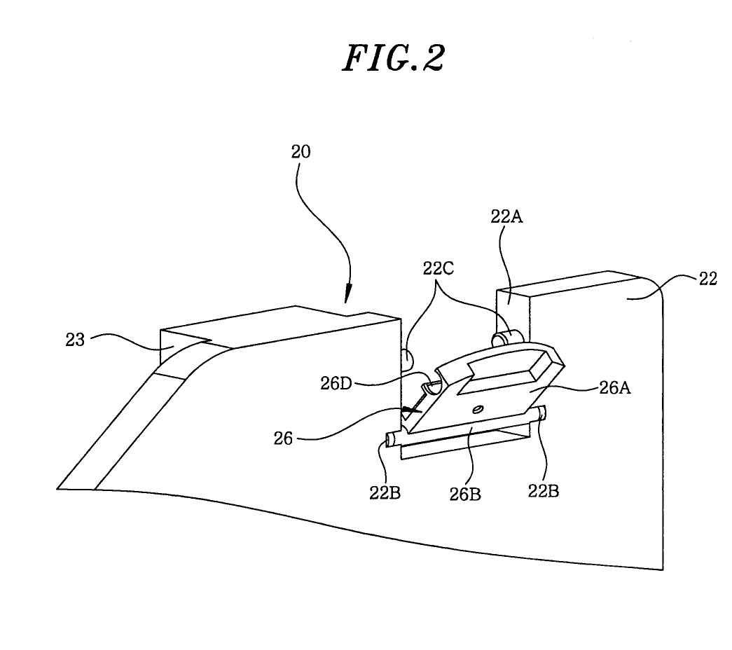

The clamping member 26 has a substantially rectangular plate-like shape as shown in FIGS. 2 to 3C. As shown in the drawings, the clamping member 26 has a main body 26A; a pin 26B attached to the lower end portion of the main body 26A with both of the left and right end thereof protruded outward from the main body 26A; a protrusion 26C disposed slightly upward from the pin 26B at a central portion in the widthwise direction of the rear surface of the main body 26A; and a pair of pin grooves 26D formed, at the left and the right end portion of the main body 26A, on the rear surface thereof. The clamping member 26 is pin-coupled to the cutoff portion 22A of the support 22.

As shown in FIG. 2, insertion grooves 22B for freely rotating the end portions of the pin 26B of the clamping member 26 are formed at the lower end portions of both side surfaces of the cutoff portion 22A of the support 22. Further, pins 22C corresponding to the pin grooves 26D of the clamping member 26 is attached to both side surfaces of the cutoff portion 22A. Accordingly, when the clamping member 26 is rotated about the pin 26B and inserted into the cutoff portion 22A of the support 22, the pin grooves 26D are engaged with the pins 22C of the cutoff portion 22A, and thus the clamping member 26 is fixed. The protruding height h (see FIG. 3C) of the protrusion 26C of the clamping member 26 from the main body 26A is such that the holding part 20 can be firmly engaged with the side surface 11A of the wafer case 10 by removing rattling between the first and the second engaging protrusions 24 and 25 and the first and the second protrusions 12 and 13 by means of bringing the clamping member 26 into pressurized contact with the bottom surface of the first depressed portion 11B while the pin grooves 26D are engaged with the pins 22C of the cutoff portion 22A.

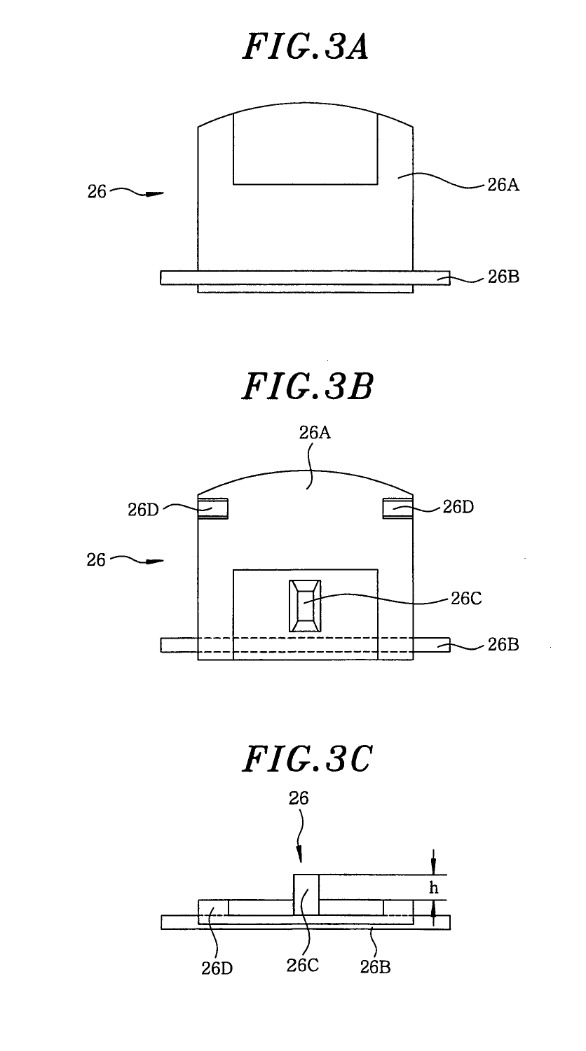

Further, a holding part 20A shown in FIG. 4 has the same configuration as that of the above-described embodiment, except that manipulation portion 21 are formed at the lower end portion of support 22. The position of the manipulation portion 21 in the support 22 can be changed according to the type of an unmanned transfer vehicle. Although not shown in FIG. 4, first and second protrusions are formed in first depressed portions 11B and a second depressed portion 11C of a wafer case 10, and first and second engaging protrusions corresponding to the first and the second protrusions are formed in the holding part 20A. Further, a clamping member is mounted to the support 22.

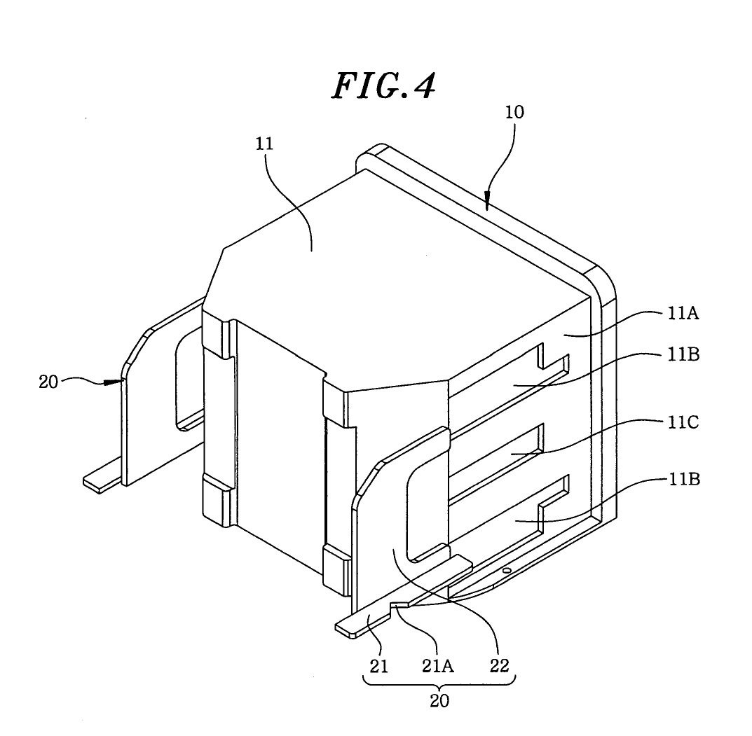

Further, in the above-described embodiment, it has been described that the first and the second protrusions 12 and 13 are provided in the first depressed portions 11B and the second depressed portion 11C of the side surface 11A of the wafer case 10, respectively, and the grooves 12A and 13A are formed between the first protrusions 12 and the first depressed portions 11B and between the second protrusions 13 and the second depressed portion 11C, respectively. However, as shown in FIG. 5, the grooves 12A and 13A may be formed by protrusions 14 protruding in directions facing with each other at the upper and the lower edge of each first depressed portion 11B and the second depressed portion 11C, respectively.

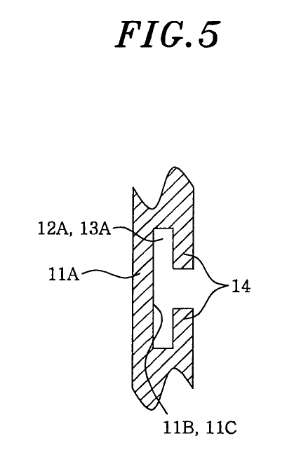

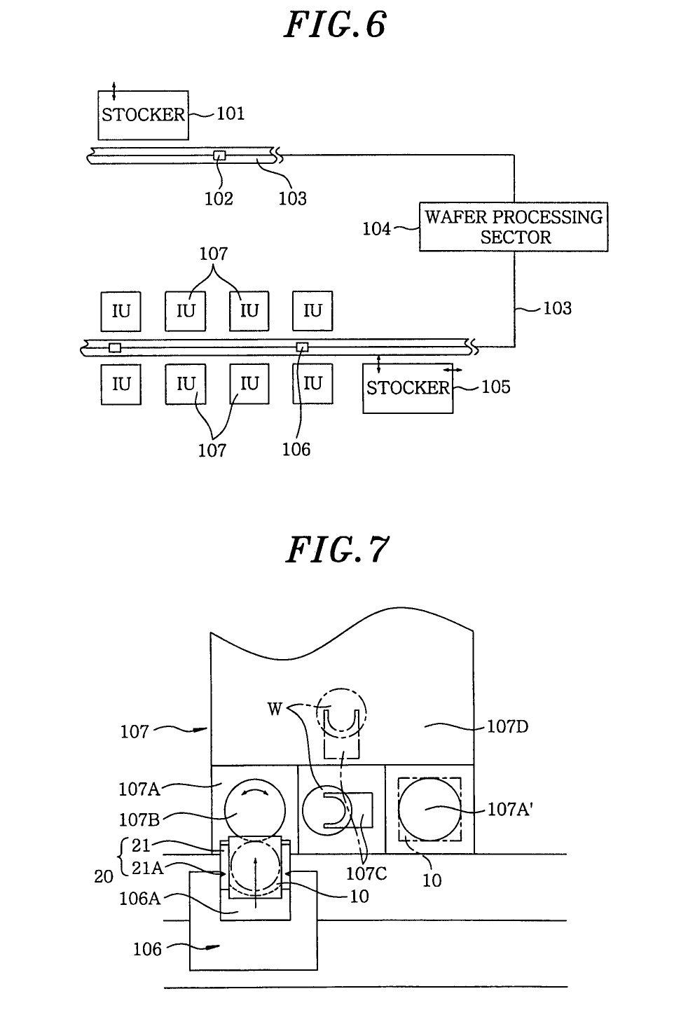

Next, a method for handling a wafer case and a method for transferring a wafer case in accordance with the embodiments of the present invention will be described with reference to FIGS. 6 and 7.

First, a specific number of semiconductor wafers is accommodated in a wafer case 10 by a wafer manufacturer, and then, the wafer case 10 accommodating therein the semiconductor wafers is transferred from the wafer manufacturer to a device manufacturer. By the device manufacturer, the wafer case 10 accommodating therein the semiconductor wafers is carried into a factory and received into a stocker 101 in a clean room of the factory.

Since the device manufacturer forms a device in the semiconductor wafer, before the semiconductor wafer is supplied to various wafer treatment processes, grips on both side surfaces 11A of the wafer case 10 are separated and then a holding part 20 is attached to each side surface 11A of the wafer case 10 as shown in FIGS. 1A and 1B. To be specific, as shown in FIG. 1A, if the holding part 20 is slid from the rear surface side to the front surface side of the wafer case 10 after bringing the first and the second engaging protrusions 24 and 25 of the holding part 20 into contact with the side surface 11A of the wafer case 10 and aligning the first and the second engaging protrusions 24 and 25 with the first and the second protrusions 12 and 13, respectively, the first and the second engaging protrusions 24 and 25 are inserted into the grooves 12A and 13A of the first and the second protrusions 12 and 13, respectively, and thus, the first and the second engaging protrusions 24 and 25 are connected with the first and the second protrusions 12 and 13, respectively. In this state, there exist slight rattling between the first engaging protrusions and the first protrusions 12 and between the second engaging protrusions 25 and the second protrusions 13.

After that, if the respective clamping members 26 attached to the upper and the lower portion of the support 22 is pushed into the cutoff portion 22A of the support 22 by raising the clamping member 26 to rotate about the pin 26B, the pin grooves 26D of the clamping member 26 are engaged with the pins 22C of the cutoff portion 22A, and simultaneously, the protrusion 26C is brought into pressurized contact with the bottom surface of the first depressed portion 11B of the wafer case 10. From this, rattling between the first engaging protrusions 24 and the first protrusions 12 and between the second engaging protrusions 25 and the second protrusions 13 are removed, so that the holding part 20 can be firmly fixed to the side surface of the wafer case 10. Accordingly, the holding part 20 is prevented from being separated from the wafer case 10.

As shown in FIG. 6, the wafer case 10 whose grips are replaced by the holding part 20 is kept in the stocker 101. When various treatments are performed on a semiconductor wafer, an unmanned transfer vehicle 102 is driven to move toward a loading/unloading port of the stocker 101 along an automatic transfer line 103. Thereafter, if a transfer arm (not shown) of the unmanned transfer vehicle 102 is driven to move toward the loading/unloading port of the stocker 101 and reach the wafer case 10, the transfer arm is raised to lift the wafer case 10 up via the manipulation portions 21 of the holding part 20. The transfer arm transports the wafer case 10 to a loading table of the unmanned transfer vehicle 102 while holding the wafer case 10.

Subsequently, as shown in FIG. 6, the unmanned transfer vehicle 102 moves along the automatic transfer line 103 to perform various wafer treatment processes in a wafer processing sector 104 and transports the waver case 10 into stockers (not shown) provided for the wafer processing sector 104. Further, in the respective treatment processes performed in the wafer processing sector 104, an unmanned transfer vehicle (not shown) moves to transfer the wafer case 10 between the stocker and a treatment unit. In this case, in each treatment process, the wafer case 10 is transferred by the unmanned transfer vehicle (not shown) dedicated to the corresponding treatment process. And also, the wafer case 10 may be transferred by the unmanned transfer vehicle 102. When the treatments are completed by automatically opening and closing the opening/closing cover of the wafer case 10 in the respective treatment processes and transferring the semiconductor wafer into the respective treatment units, the wafer case 10 is transferred from the unmanned transfer vehicle 102 to the stocker of the final treatment process and kept therein. Thereafter, the wafer case 10 is transferred from the stocker to, e.g., a stoker 105 of an inspection process and kept therein.

In the inspection process, an unmanned transfer vehicle 106 used in the inspection process moves between the stocker 105 and a plurality of inspection units (IU) 107 along the automatic transfer line 103 to transfer the wafer case 10. In this case, the wafer case 10 is transferred with the opening/closing cover thereof being opened (open cassette). If an opening/closing unit of the opening/closing cover is installed in the inspection units, the wafer case 10 is transferred with the opening/closing cover being closed. As shown in FIG. 7, when the unmanned transfer vehicle 106 is stopped at a side of the inspection unit 107, a transfer arm 106A of the unmanned transfer vehicle 106 is driven to raise the wafer case 10 from a loading table via the manipulation portion 21 of the holding part 20 mounted to the wafer case 10. At this time, the transfer arm 106A aligns the positions of the transfer arm 106A and the wafer case 10 by using the cutoff portion 21A formed in the manipulation portion 21. Thereafter, the transfer arm 106A transfers the wafer case 10 to a loading port 107A of the inspection unit 107 and loads the wafer case 10 on the loading port 107A.

In the inspection unit 107, if the loading port 107A receives the wafer case 10, a turn table 107B is rotated so that the loading/unloading port of the wafer case 10 faces a wafer transfer mechanism 107C. The wafer transfer mechanism 107C unloads the semiconductor wafer one by one from the wafer case 10 and transfers the semiconductor wafer to an inspection chamber 107D to perform an inspection. While an inspection on the semiconductor wafer in the wafer case 10 is performed, the unmanned transfer vehicle 106 transfers the next wafer case 10 from the stocker 105 to another loading port 107A′ as indicated in a dashed dotted line. In this manner, inspections of semiconductor wafers are performed continuously without a stop after inspections on all semiconductor wafers in the prior wafer case 10 are performed. Further, the unmanned transfer vehicle 106 transfers the wafer case 10 between the stocker 105 and the respective inspection units 107 so that the inspections can be continuously performed.

When the inspection on the semiconductor wafers in the wafer case 10 is completed in one inspection unit 107, the unmanned transfer vehicle 106 unloads the wafer case 10 from the loading port 107A and then returns it to its original place in the stocker 105. The wafer case 10 which has returned to the stocker 105 is transferred to another inspection unit 107 by the unmanned transfer vehicle 106. After various treatments in a clean room are completed, the wafer case 10 is transferred from a stoker (not shown) in a factory to another factory. At this time, the holding parts 20 are detached from the wafer case 10 and then the original grips are attached thereto.

As described above, in accordance with the embodiments of the present invention, the wafer case 10 in which the grips can be attached and detached to and from both side surfaces 11A of the wafer case 10 is handled in the automatic transfer line 103 while the grips are detached from the wafer case 10 and the holding parts 20 enabling the unmanned transfer vehicle 102 or 106 to hold the wafer case 10 are attached to the positions at which the grips have been separated. Further, the wafer case is handled while the holding parts 20 are detached from the wafer case 10 and the grips are attached thereto when the wafer case is not handled in the automatic transfer line 103. Hence, since the wafer case 10 for use in a transfer between factories can be handled as a wafer case 10 for use in the automatic transfer line 103 in a clean room by simply replacing the grips of the wafer case 10 with the holding part 20, transfer works of a semiconductor wafer between wafer cases of different types are not required and the handling of the wafer case 10 can be simplified. Moreover, the handling cost of the wafer case 10 can be reduced. Accordingly, wafer cases of two types, i.e., the FOSB and the FOUP, are not necessary like in the prior art and it is sufficient to provide the FOSB, thereby reducing the cost for the wafer case 10.

Further, in accordance with the embodiments of the present invention, the wafer case 10 in which the grips can be attached and detached to and from the both side surfaces 11A of the wafer case 10 is held and transferred by the holding parts 20 while the grips are detached from the wafer case 10 and the holding parts 20 enabling the unmanned transfer vehicle 102 or 106 to hold the wafer case 10 are attached to the positions at which the grips have been separated. Therefore, the wafer case 10 can be transferred when it is handled in the automatic transfer line 103 and also is not handled in the automatic transfer line 103. Accordingly, wafer cases of two types, i.e., the FOSB and the FOUP, are not necessary like in the prior art and it is sufficient to provide the FOSB, thereby reducing the cost for the wafer case 10.

Further, in accordance with the embodiments of the present invention, the holding part 20 includes the manipulation portion 21 for use by the unmanned transfer vehicle 102 or 106; the support 22 for supporting the manipulation portion 21 by a front surface thereof; and the first and the second engaging protrusions 24 and 25 formed on the rear surface of the support 22 to be connected to the first and the second protrusions 12 and 13 formed on the side surface of the wafer case 10, respectively. And thus, the holding part 20 can be simply attached to the wafer case 10 by simply connecting the first and the second engaging protrusions 24 and 25 to the first and the second protrusions 12 and 13 of the side surface 11A of the wafer case 10, respectively, thereby simplifying the handling of the wafer case 10. Further, since the clamping members 26 for attaching and fixing the first and the second engaging protrusions 24 and 25 to the first and the second protrusions 12 and 13, respectively, are provided in the support 22, the holding part 20 can be firmly fixed to the wafer case 10, so that the unmanned transfer vehicle 102 or 106 can firmly transfer the wafer case 10.

Further, the present invention is not limited to the above-described embodiments, but the elements can be properly changed if necessary. The gist is that, all the cases in which a wafer case of one type can cope with a transfer between factories, between treatment processes in factories, and in a treatment process by simply replacing the grips of the wafer case with a holding part belong to the present invention.

The present invention can be suitably used to transfer a semiconductor wafer.

While the invention has been shown and described with respect to the embodiments, it will be understood by those skilled in the art that various changes and modification may be made without departing from the scope of the invention as defined in the following claims.

1. A method for handling a wafer case having attachable and detachable grips, the method comprising the step of:
handling the wafer case in an automatic transfer line while the attachable and detachable grips are detached from the wafer case and holding parts allowing an automatic transfer unit to hold the wafer case are attached to portions of the wafer case from which the attachable and detachable grips have been detached.

2. The method of claim 1, further comprising handling the wafer case while the holding parts are detached from the wafer case and the attachable and detachable grips are attached to the wafer case when the wafer case is not handled in the automatic transfer line.

3. The method of claim 1, wherein the portions from which the attachable and detachable grips have been detached include two side surfaces of the wafer case, respectively, and
wherein the method includes attaching said holding parts to said two side surfaces for handling in the automatic transfer line.

4. A method for transferring a wafer case having attachable and detachable grips, the method comprising the steps of:
detaching the attachable and detachable grips from the wafer case, and
attaching holding parts allowing an automatic transfer unit to hold the wafer case to portions of the wafer case from which the attachable and detachable grips have been detached,
wherein the automatic transfer unit transfers the wafer case while holding the wafer case by using the holding parts.

5. The method of claim 4, further comprising detachably attaching the attachable and detachable grips to two side surfaces of the wafer case, respectively, when the wafer is not handled in the automatic transfer line.

6. The method of claim 1, further including providing as the holding parts, holding parts which comprise:
a manipulation portion for use by the automatic transfer unit;
a support for supporting the manipulation portion by a surface thereof; and
a connecting portion, formed on another surface of the support, for being connected with a connected portion formed on a side surface of the wafer case.

7. The method of claim 6, further including providing the connected portion which includes at least one pair of grooves formed on the side surface of the wafer case, and
providing the connecting portion which includes at least one pair of engaging portions engaging with said at least one pair of grooves, respectively.

8. The method of claim 7, further including providing said at least one pair of grooves as grooves which are formed by protrusions protruding from the side surface of the wafer case in opposite directions with each other, and
wherein the pair of engaging portions are formed by engaging protrusions protruding in directions opposite to the protruding directions of the protrusions of said at least one pair of grooves.

9. The method of claim 6, further including providing the support with clamping members for fixing the holding part to the wafer case by bringing the connected portion into close contact with the connecting portion.

10. The method of claim 4, further including providing as the holding parts, holding parts which comprise:
a manipulation portion for use by the automatic transfer unit;
a support for supporting the manipulation portion by a surface thereof; and
a connecting portion, formed on another surface of the support, for being connected with a connected portion formed on a side surface of the wafer case.

11. The method of claim 10, further including providing the connected portion which includes at least one pair of grooves formed on the side surface of the wafer case, and
wherein the connecting portion includes at least one pair of engaging portions engaging with said at least one pair of grooves, respectively.

12. The method of claim 11, further including providing said at least one pair of grooves as grooves which are formed by protrusions protruding from the side surface of the wafer case in opposite directions with each other, and
wherein the pair of engaging portions are formed by engaging protrusions protruding in directions opposite to the protruding directions of the protrusions of said at least one pair of grooves.

13. The method of claim 10, including providing the support with clamping members for fixing the holding part to the wafer case by bringing the connected portion into close contact with the connecting portion.

14. The method of claim 8, further comprising providing each of the engaging protrusions with an L shape.
